(19) United States
(12) Patent Application Publication
(10) Pub. No.: US 2011/0048313 A1
(43) Pub. Date: Mar. 3, 2011

(54) INDICATING THERMAL DOSAGE EXPOSURE OF ELECTRIC LAMPS

(75) Inventors: Zoltan Bako, Dunakeszi (HU); Istvan Magai, Biatorbagy (HU); Adrienn Imre, Budapest (HU)

(73) Assignee: General Electric Company

(21) Appl. No.: 12/553,250

(22) Filed: Sep. 3, 2009

(51) Int. Cl. G01K 1/02; C23C 16/52

(52) U.S. Cl. 116/216; 427/8

(57) ABSTRACT

A thermal dosage indicator for an electric lamp provides real time indication of time and temperature exposure of the lamp. In one version, a coating on a designated portion of the lamp changes color upon exposure to different combinations of time and temperature. In another version, a semiconductor is mounted on the surface at a designated location on the lamp and the electrical properties of the semi conductor monitored to give an indication of thermal dosage exposure. In another version, a carbon cell of predetermined dimension is mounted on the lamp surface and is monitored at specified intervals to determine dimensional changes from thermal sublimation to give an indication of thermal dosage.

### BACKGROUND OF THE DISCLOSURE

Electric lamps, particularly incandescent halogen lamps of the type employed for automotive applications, have experienced premature failures in service; and, it has been quite difficult to determine whether the failure was due to faulty lamp construction or intervals of exposure to excessive supply voltage to the lamp. Excessive supply voltage, even for a relatively limited interval, can cause the lamp to operate at above-normal temperatures which results in shortening the expected life of the lamp as expected with the nominal supply voltage. Where the lamp is exposed to excessive supply voltages for such limited periods, it is virtually impossible to detect such occurrences by visual examination of the lamp until failure occurs.

Thus, it has been long desired to provide a way or means of determining whether an electric lamp has been exposed to over voltage in service resulting in excessive temperatures of the lamp. It has been desired to provide such a determination of excessive voltage in a manner which is readily detectable by the user during service and by the manufacturer after the lamp has failed.

In addition, when the lamp is put into service with insufficient air circulation thereabout, even at nominal operating voltage, the lamp can experience excessive temperatures resulting in premature failure.

### SUMMARY OF THE DISCLOSURE

The present disclosure describes a technique for providing visual indication on a an electric lamp of the thermal dosage the lamp has been exposed to during service, and particularly thermal dosage resulting in temperatures considered to be excessive in terms of the normal expected operating voltage for the lamp. In one version, thermally responsive coating is applied to a selected spot on the lamp or its base. The coating is responsive to exhibit different colors based upon the temperature to which the coating has been exposed and the time that the lamp was exposed to such excessive temperature which together provide an indication of a thermal dosage. This information may then be used to determine the reduction in the expected service life of the lamp. In another version, a semiconductor element is attached to a designated portion of the exterior surface of the lamp or either one of the interior or exterior of its base and the electrical properties found in the semiconductor are monitored during service. From a look-up table of electrical properties as a function of temperature, it can be determined what temperatures the lamp has experienced during sensing of the certain electrical properties. In another version, a cell of carbon material of predetermined dimensions is disposed in a designated area of the surface of the lamp or its base and; upon operation of the lamp the dimensions of the carbon may be measured at intervals. From a look-up table of changes in the dimensions as a function of thermal dosage, it can be determined what temperatures the lamp has experienced during the intervals. From this information the reduction in normal service life due to exposure to the high temperatures for a particular interval can be estimated. Carbonaceous material may also be employed as a cell of predetermined dimensions.

The disclosure describes a way or means to determine the operating temperature exposure and cumulative time of operation of the lamp; and, from the combination of these two, the cumulative thermal dosage is determined.

### BRIEF DESCRIPTION OF THE DRAWINGS

FIG. 1 is a side elevation view of an electric lamp with portions of the bulb broken away to illustrate the internal elements;

FIG. 2 is a portion of a view of the upper segment of the bulb of an electric lamp; and,

FIG. 3 is a look-up table of temperature as a function of expected life.

### DETAILED DESCRIPTION OF THE PREFERRED EMBODIMENTS

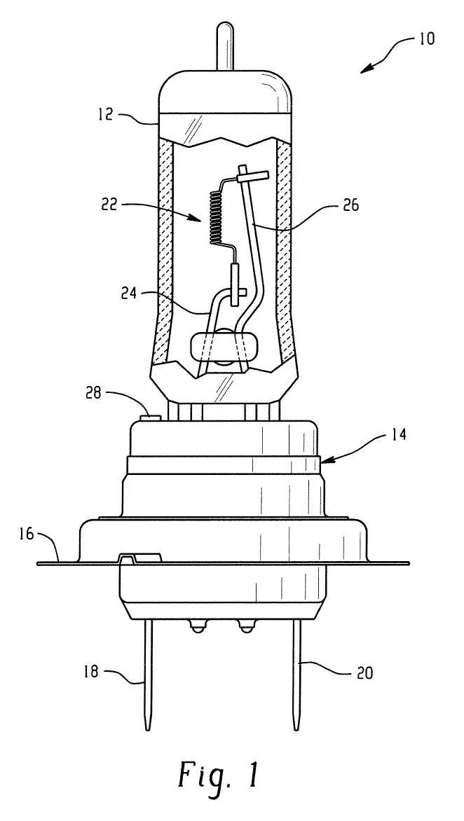

Referring FIG. 1, an electric lamp according to the present disclosure is indicated generally at 10 an includes a bulb attached to a base indicated generally at 14 which may be attached to a support structures such as 16, as for example, the sheet metal portions of the structure of a motor vehicle. The lamp 10 includes a pair of externally extending terminals 18, 20 which may be engaged with a suitable receptacle (not shown) or connected to a wiring harness (not shown). Bulb 12 may be formed of suitable transparent glass material and houses the illuminating element that is indicated generally at 22 which is connected via electrodes 24, 26 to the terminals 18, 20 respectively.

A spot of thermally responsive coating 28 is provided on a designated region of portion of the base 14; and, the coating 28 is formed of suitable materials such as acrylate/resin and changes color as the coating is exposed to elevated temperatures for various time intervals. The coating may alternatively be provided on a designated region of an internal surface portion of the base 14.

Referring FIG. 3, a graphical presentation of temperature and exposure of time in hours is shown for various combinations of temperature and time wherein the color of the coating may be determined from the numeral indicated in the graph. Table 1 gives the color description for the numerical values shown in FIG. 3.

TABLE 1

| Ref. Numeral | Color Description |
|---|---|
| 1 | hardly darkening |
| 2 | visible darkening |
| 3 | yellowed, coloring |
| 4 | browned, coloring |
| 5 | black: burned |

From FIG. 3 and Table 1, it will be readily seen that the higher the temperature exposure of the lamp the shorter interval is required to produce the greatest change in the thermal dosage indicating coating.

In the present practice, it has been found satisfactory to employ a material for the coating 28 of the version of FIG. 1 having a manufacturers designation K2 experimental mix and obtainable from Budalakk Innova Kft., 1044 Budapest, Váci út40. The acrylate/resin coating exhibits the properties of turning to the color brown at 20 hours exposure to 230 degrees centigrade, the color of yellow at 40 hours exposure to 220 degrees centigrade and the color of black at 60 hours exposure to 250 degrees centigrade with no visible color change at 60 hours exposure to 200 degrees centigrade.

Alternatively, the thermally responsive coating 28 may be replaced by a temperature indicating semiconductor which is electrically connected to circuitry for monitoring the electrical properties of the semiconductor. In this version, the change in electrical properties of the semiconductor may be compared with a look-up table (not shown) of values of temperature as a function of the electrical properties such as drain current change; and, thus the temperature exposure of the lamp determined by the change in electrical properties.

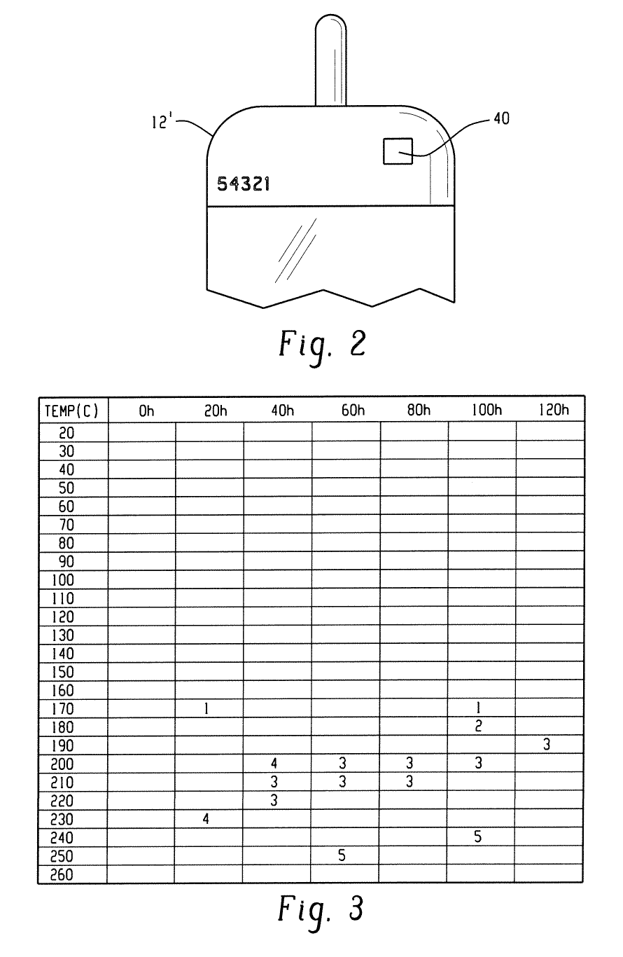

Referring to FIG. 2, another version of the technique of the present disclosure is illustrated wherein the thermally responsive coating material is deposited on the bulb 12′ with numerals in reverse order, e.g. (5,4,3,2,1); and, the material for each numeral is of a different thickness layer or weakness insofar as thermal dosage produces change in appearance. For example, for the indicated 5 reference numerals in FIG. 2, after 100 hours exposure only numerals 2, 3, 4, 5 would be visible; after 300 hours exposure only numerals 4 and 5 would be visible and after 500 hours exposure none of the numerals would be visible. It would be understood that other combinations of indicia and temperature may be employed for the reference characters.

With continued reference to FIG. 2, an alternative version of the technique of the present disclosure is illustrated in the form of a carbon cell thermal dosage indicator 40 which is initially formed to predetermined dimensions; and, as the carbon is exposed to higher temperatures, sublimation occurs and the dimensions of the cell are reduced. From the look up table (not shown) of dimensions of the cell versus time at temperature the thermal dosage to which the cell has been exposed by its presence on the surface of the bulb can be determined.

Alternatively, the cell 40 may be formed of suitable carbonaceous material which exhibits the properties of sublimation at temperature as does the carbon material cell.

The present disclosure thus describes a technique for providing an indication in real time of the thermal dosage or time at temperature exposure of an electric lamp in service, particularly to excessive temperatures such as would be caused by excessive voltage applied to the lamp. In one version, a coating applied to a designated region of the lamp undergoes different color changes when exposed to different combinations of temperature of specified intervals. In another version, a semiconductor is monitored for changes in its electrical properties to give an indication of the thermal exposure of the semiconductor on the lamp. In another version, carbon or carbonaceous material in the form of a cell of specified dimensions is applied to the surface of the lamp; and, changes in the dimension of the cell leads to sublimation from temperature exposure employed to determine the degree of thermal dosage to which the cell has been exposed. The technique of the present disclosure thus provides the unique and simple way of determining whether an electric lamp has been exposed to excessive thermal dosage or high temperatures for specified intervals of time which would result in a reduction in the normal expected life.

The invention has been described with reference to the preferred embodiments. Obviously, modifications and alterations will occur to others upon reading and understanding the preceding detailed description. It is intended that the invention be construed as including all such modifications and alterations and is limited only by the following claims.

What is claimed is:

1. A method of indicating thermal dosage exposure for use with electric lamps comprising:
(a) applying a coating of temperature responsive synthetic material to a designated portion of the outer surface of the lamp;
(b) operating the lamp in the intended service application;
(c) examining the coating color and comparing the results with a look-up table of coating color as a function of time-at-temperature for various temperatures; and,
(d) determining from the look-up table whether the lamp has been exposed to excessive temperature so as to bring about significantly shortened lamp life.

2. The method defined in claim 1, wherein the step of applying a coating includes applying a synthetic paint material.

3. The method defined in claim 2, wherein the step of applying synthetic paint includes applying K2 experimental mix.

4. The method defined in claim 1, wherein the step of applying a coating includes applying paint exhibiting a color of brown at 20 hours exposure to 230° C., a color of yellow at 40 hours exposure to 220° C. and a color of black at 60 hours exposure to 250° C. with no visible color change at 60 hours exposure to 200° C.

5. The method defined in claim 1, wherein the step of applying a coating includes applying a coating to the base region of the lamp.

6. The method defined in claim 1, wherein the step of applying a coating includes applying a coating of a mixture of acrylate and resin material.

7. A method of indicating thermal dosage exposure for use with electric lamps comprising:
(a) disposing a semiconductor on a designated portion of one of the outer or inner surface of the lamp;
(b) operating the lamp in its extended application and monitoring the electrical properties of the semiconductor during lamp operation; and,
(c) comparing the electrical properties with a look-up table of properties as a function of temperature and determining from changes in the semiconductor electrical properties whether the lamp has experienced an over temperature condition during operation.

8. The method defined in claim 6, wherein the step of applying a semiconductor includes applying a semiconductor in the region of the top of the lamp.

9. A method of indicating thermal dosage exposure for use with electric lamps comprising:
(a) disposing a cell of carbon material of predetermined dimensions in a designated area of the surface of the lamp;
(b) operating the lamp in its intended application; and,
(c) determining the change in the dimensions of the carbon during lamp operation; and,
(d) comparing the changes in dimension with values in a look-up table of changes in dimension as a function of thermal dosage; and,
(e) determining whether the lamp has been exposed to excessive thermal dosage so as to shorten the expected service life of the lamp.

10. The method defined in claim 8, wherein the step of disposing a cell of carbon material includes disposing a cell in the region of the top of the lamp.

11. An electric lamp having a thermal dosage indicator comprising:
(a) a base with electrodes thereon and an illuminating bulb attached to the base;
(b) a coating of temperature responsive synthetic material disposed on a designated portion of one of the outer or inner surface of one of (a) the bulb and (b) the base; and,
(c) said coating being responsive to exhibit no visible color change upon exposure to 200° C. for 60 hours, exhibit a color of brown upon exposure to 230° C. for 20 hours, exhibit a color of yellow upon exposure to 220° C. for 40 hours and exhibit a color of black upon exposure to 250° C. for 60 hours.

12. The lamp defined in claim 11, wherein said coating comprises K2 experimental mix paint material.

13. An electric lamp having a thermal dosage indicator comprising:
(a) a base with electrodes thereon and an illuminating bulb;
(b) a semiconductor disposed on a designated portion of one of (a) the base and (b) the bulb, wherein predetermined measurable changes in electrical properties of the semiconductor are indicative of lamp exposure to excessive thermal dosage of the lamp.

14. The lamp defined in claim 13, wherein the semiconductor exhibits a change of drain current upon exposure of the lamp to excessive thermal dosage.

15. An electrical lamp having a thermal dosage indicator comprising:
(a) a lamp having a base with electrodes thereon;
(b) an illuminating bulb attached to the base;
(c) a cell of carbonaceous material of predetermined dimension disposed on a designated region of the surface of one of (a) the base and (b) the illuminating bulb; and,
(d) the cell changing dimensions by thermal sublimation such that a predetermined change occurs upon exposure of the lamp to excessive thermal dosage.
